(19) United States
(12) Patent Application Publication
(10) Pub. No.: US 2025/0218041 A1
(43) Pub. Date: Jul. 3, 2025

(54) METHOD AND APPARATUS WITH SCANNING ELECTRON MICROSCOPE IMAGE CORRECTION

(71) Applicant: SAMSUNG ELECTRONICS CO., LTD., Suwon-si (KR)

(72) Inventors: Sungun PARK, Suwon-si (KR); Minsu KO, Suwon-si (KR); Junhyun NAM, Suwon-si (KR); In Seok PARK, Suwon-si (KR); Sung Yoon RYU, Suwon-si (KR); Sungjoo SUH, Suwon-si (KR); Minsu AHN, Suwon-si (KR)

(73) Assignee: SAMSUNG ELECTRONICS CO., LTD., Suwon-si (KR)

(21) Appl. No.: 18/982,554

(22) Filed: Dec. 16, 2024

(30) Foreign Application Priority Data
Jan. 3, 2024 (KR) 10-2024-0001168

(51) Int. Cl. G06T 7/80; G06T 7/00

(52) U.S. Cl. CPC G06T 7/80; G06T 7/0004; G06T 2207/10061; G06T 2207/20081; G06T 2207/20084; G06T 2207/30148

(57) ABSTRACT

A processor-implemented method including acquiring a first image a first wafer at a first time point, acquiring a second image of the first wafer at a second time point after a predetermined amount of time from the first time point, estimating a calibration factor by using the first image and the second image, and correcting a third image of a second wafer by using the calibration factor.

### CROSS-REFERENCE TO RELATED APPLICATION

This application claims priority to and the benefit of Korean Patent Application No. 10-2024-0001168 filed in the Korean Intellectual Property Office on Jan. 3, 2024, the entire contents of which are incorporated herein by reference.

### BACKGROUND

### (a) Field

The present disclosure relates to a method and apparatus with scanning electron microscope image correction.

### (b) Description of the Related Art

Typically, when measuring a depth from an image of a scanning electron microscope (a SEM image), only a characteristic that an amount of a BSE is reduced and then an image becomes dark is used. However, in order to measure a nanometer depth, a change in the amount of fine electrons alone increases a measurement error In addition, there is no typical method available to correct errors that occur due to changes in the SEM image due to changes in an amount of an electron irradiation and an amount of reflected electrons after preventive maintenance is conducted on or provided to the device.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a processor-implemented method including acquiring a first image of a first wafer at a first time point, acquiring a second image of the first wafer at a second time point after a predetermined amount of time from the first time point, estimating a calibration factor by using the first image and the second image, and correcting a third image of a second wafer by using the calibration factor.

The method may include acquiring the first image including acquiring the first image by using a first scanning electron microscope and acquiring the second image may include including the second image by using a second scanning electron microscope.

The acquiring of the second image may include determining the second time point as a specific time point that requires the correction of the first image after the first time point.

The determining of the specific time point may include determining a time point at which a difference extracted by comparing a first result obtained by inputting the first image into a training model and a second result obtained by inputting the second image into the training model satisfies a predetermined condition as a specific point when the correction is required.

The acquiring of the first image may include specifying the first time point as a time point before performing a preventive maintenance of a scanning electron microscope that acquires one or more of the first image, the second image, and the third image and the acquiring of the second image may include specifying the second time point as a time point after performing the preventive maintenance.

The correcting of the third image may include correcting the third image acquired from the second wafer through the calibration factor by using a scanning electron microscope after performing the preventive maintenance.

The method may include determining that the preventive maintenance of the scanning electron microscope is necessary if an estimated value of the calibration factor is outside a management value range.

The estimating of the calibration factor may include adjusting a candidate calibration factor until a first result obtained by inputting the first image into a training model and a second result obtained by inputting the second image together with the candidate calibration factor into the training model are the same and estimating the candidate calibration factor input along with the second image as a calibration factor when the first result and the second result are the same.

The estimating of the calibration factor may include obtaining a specific calibration factor that matches a first result of a first system for the first image and a second result of a second system for the second image through neural network.

The correcting of the third image may include inputting the third image along with the calibration factor to a training model of a neural network.

In a general aspect, here is provided an electronic apparatus including processors configured to execute instructions and a memory storing the instructions, and execution of the instructions configures the processors to acquire a first image of a scanning electron microscope from a first wafer at a first time point, acquire a second image of the scanning electron microscope from the first wafer at a second time point a predetermined period of time after the first time point, estimate a calibration factor by using the first image and the second image, and correct a third image of another scanning electron microscope acquired from a second wafer by using the calibration factor.

The acquiring of the first image may be performed using a first scanning electron microscope and the acquiring of the second image may be performed by using a second scanning electron microscope.

The acquiring of the second image may include determining the second time point as a specific time point that the correction of the first image is necessary after the first time point.

The acquiring of the second image may include determining a time point when a difference extracted by comparing a first result obtained by inputting the first image into a training model and a second result obtained by inputting the second image into the training model satisfies a predetermined condition as a specific time point that the correction is necessary.

The acquiring of the first image may include specifying the first time point as a prior-time point before performing preventive maintenance of the scanning electron microscope and the acquiring of the second image may include specifying the second time point as a post-time point after performing the preventive maintenance.

The correcting may include correcting the third image acquired from the second wafer by using the other scanning electron microscope after performing the preventive maintenance through the calibration factor.

The estimating of the calibration factor may include adjusting a candidate calibration factor until a first result obtained by inputting the first image into a training model and a second result obtained by inputting the second image together with the candidate calibration factor into the training model are the same and, when the first result and the second result are the same, the candidate calibration factor input along with in the second image may be estimated as the calibration factor.

The estimating of the calibration factor may include obtaining a specific calibration factor that matches a first result of a first system for the first image and a second result of a second system for the second image through trained neural network model.

The processor may be further configured to determine that a preventive maintenance of the scanning electron microscope is necessary if an estimated value of the calibration factor is outside a management value range.

The correction of the third image may include inputting the third image along with the calibration factor into a training model of a neural network.

### BRIEF DESCRIPTION OF THE DRAWINGS

FIG. 1 is an example process of a scanning electron microscope image correction according to one or more embodiments.

FIG. 2 is an example method of correcting a scanning electron microscope image according to one or more embodiments.

FIG. 3 is an example process of correcting a scanning electron microscope image according to one or more embodiments.

FIG. 4 is an example process of correcting a scanning electron microscope image according to one or more embodiments.

FIG. 5 is an example electronic apparatus with scanning electron microscope image correction according to one or more embodiments.

FIG. 6 is an example method of a scanning electron microscope image according to one or more embodiments.

FIG. 7 is a graph illustrating an example preventive maintenance determining reference according to one or more embodiments.

FIG. 8 illustrates an example electronic apparatus according to one or more embodiments.

Throughout the drawings and the detailed description, unless otherwise described or provided, the same, or like, drawing reference numerals may be understood to refer to the same, or like, elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied In different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

As used in connection with various example embodiments of the disclosure, any use of the terms “module” or “unit” means hardware and/or processing hardware configured to implement software and/or firmware to configure such processing hardware to perform corresponding operations, and may interchangeably be used with other terms, for example, “logic,” “logic block,” “part,” or “circuitry”. As one non-limiting example, an application-predetermined integrated circuit (ASIC) may be referred to as an application-predetermined integrated module. As another non-limiting example, a field-programmable gate array (FPGA) or an application-specific integrated circuit (ASIC) may be respectively referred to as a field-programmable gate unit or an application-specific integrated unit. In a non-limiting example, such software may include components such as software components, object-oriented software components, class components, and may include processor task components, processes, functions, attributes, procedures, subroutines, segments of the software. Software may further include program code, drivers, firmware, microcode, circuits, data, database, data structures, tables, arrays, and variables. In another non-limiting example, such software may be executed by one or more central processing units (CPUs) of an electronic device or secure multimedia card.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

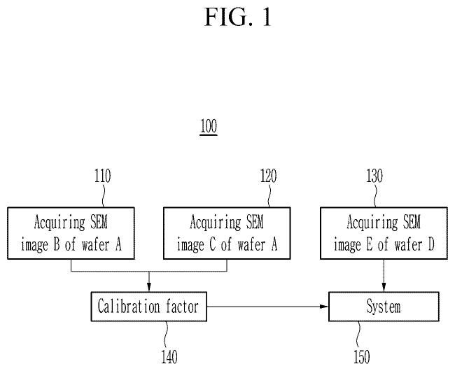

FIG. 1 is an example process of a scanning electron microscope image correction according to one or more embodiments.

The method of correcting the scanning electron microscope image may be performed through an electronic apparatus, such as a scanning electron microscope image correction apparatus.

Referring to FIG. 1, in a non-limiting example, a process for correcting a scanning electron microscope image 100 (e.g., an scanning electron microscope image correction apparatus) may include acquiring a scanning electron microscope (SEM) image B of a wafer A 110, and after a predetermined period of a time, acquire an SEM image C of the same wafer A 120.

In an example, if the characteristics of the SEM image B and the SEM image C acquired from the same wafer A change over time, the scanning electron microscope image correction apparatus may correct them.

The scanning electron microscope image correction apparatus may calculate a calibration factor 140 using the SEM image B and the SEM image C. The scanning electron microscope image correction apparatus may then input the calculated calibration factor 140 to a system 150 together with the SEM image E of another wafer D 130.

In an example, the scanning electron microscope image correction apparatus may use the calibration factor 140 to correct the SEM image acquired from the wafer over time to have the same characteristics as the SEM image acquired from an original wafer.

Here, having the same characteristic may mean that statistical characteristics of the image are similar, and, in an example, the same characteristic may refer to other similarities, which may mean that the result has the homeostasis when the corresponding images are input to the AI system.

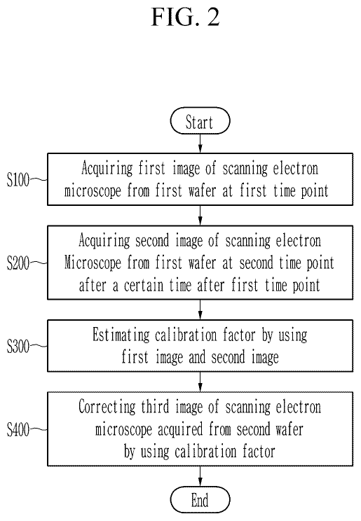

FIG. 2 is an example method of correcting a scanning electron microscope image according to one or more embodiments. The correction method of the scanning electron microscope image of FIG. 2 may be performed through an electronic apparatus (e.g., a scanning electron microscope image correction apparatus).

Referring to FIG. 2, in a non-limiting example, the scanning electron microscope image correction apparatus may acquire a first image of the scanning electron microscope from a first wafer at a first time point (S100).

In an example, the scanning electron microscope image correction apparatus may acquire a second image of the scanning electron microscope from the first wafer at a second time point after a predetermined period, or amount, of time after the first time point (S200).

The scanning electron microscope image correction apparatus may acquire the first image by using a first scanning electron microscope and the second image by using a second scanning electron microscope.

The scanning electron microscope image correction apparatus may determine that the second time point is a specific time point that requires the correction of the first image after the first time point.

In an example, the scanning electron microscope image correction apparatus may compare the first result obtained by inputting the estimated first image into a training model and the second result obtained by inputting the second image into the training model, and determine a time point when the difference extracted through the comparison satisfies a predetermined condition as the specific time point when the correction is needed.

In an example, the predetermined condition may be a case where the difference between the first result and the second result is greater than a predetermined boundary value.

The scanning electron microscope image correction apparatus may specify the first time point as a time point before performing a preventive maintenance of the scanning electron microscope, and the second time point as a time point after performing the preventive maintenance.

The scanning electron microscope image correction apparatus may estimate the calibration factor by using the first image and the second image (S300).

The scanning electron microscope image correction apparatus may adjust a candidate calibration factor until the first result obtained by inputting the first image into the training model and the second result obtained by inputting the second image together with the candidate calibration factor into the training model are the same.

In an example, an electronic apparatus including the training model may include an artificial intelligence (AI) system. For example, the artificial intelligence system may include a neural network, a trained model, an image processing system, a natural language processing system, and various production-type artificial intelligence systems.

In an example, the scanning electron microscope image correction apparatus may estimate the candidate calibration factor input along with the second image as a calibration factor when it is determined that the first result and the second result are the same or equivalent.

The scanning electron microscope image correction apparatus may obtain the specific calibration factor that matches the result of the system for the first image and the result of the system for the second image through an artificial intelligence model.

The system is not particularly limited to various systems including the artificial intelligence system. The artificial intelligence model include a deep learning model and a neural network model and is not particularly limited thereto.

In an example, the scanning electron microscope image correction apparatus may utilize statistical characteristic information of the image, such as a histogram characteristic of the acquired scanning electron microscope images, an intensity level, and an intensity ratio, or an information on minute changes in the scanning electron microscope equipment to estimate the calibration factor.

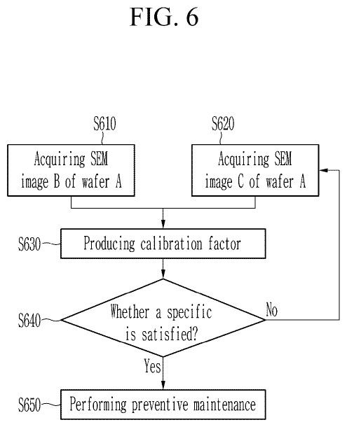

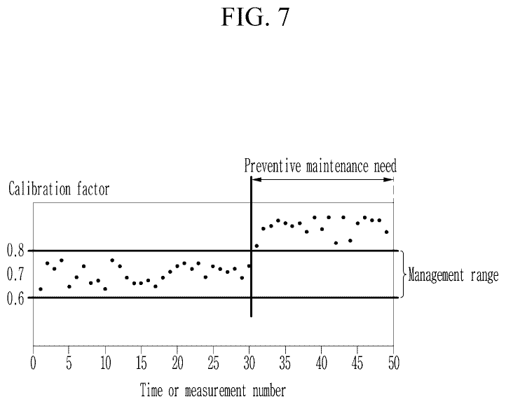

In an example, the scanning electron microscope image correction apparatus may determine that the preventive maintenance of the scanning electron microscope is necessary when the value of the estimated calibration factor is outside a management value range, as described in greater detail below with reference to FIG. 6 and FIG. 7.

In an example, the scanning electron microscope image correction apparatus may correct a third image of the scanning electron microscope acquired from the second wafer by using the calibration factor (S400).

The second wafer may be the same wafer, or a different wafer other than the first wafer that was used to estimate the calibration factor. The third image may be a scanning electron microscope image acquired at a time point after the acquisition of the first image and the second image.

The third image may be acquired using the same scanning electron microscope as the scanning electron microscope used to acquire the first image and the second image, or may be acquired using a different scanning electron microscope.

The scanning electron microscope image correction apparatus may input the third image along with the calibration factor to a training model, where, in an example, the training model of an artificial intelligence system, including a neural network.

In other words, the scanning electron microscope image correction apparatus may correct the third image so that the result of the training model output through the third image has a homeostasis (i.e., a similarity in characteristics to the first image) by inputting the third image and the calibration factor together to the training model and, thus, a stable collection of images of consistent quality may be achieved.

The scanning electron microscope image correction apparatus may correct the third image acquired from the second wafer by using the scanning electron microscope after performing the preventive maintenance through the calibration factor.

In an example, the scanning electron microscope image correction apparatus may input the image acquired through the scanning electron microscope after the preventive maintenance into the system along with the calibration factor.

In other words, the scanning electron microscope image correction apparatus may correct the image acquired through the scanning electron microscope after performing the preventive maintenance through the calibration factor input together, and may make the result value of the system to be the same as the result value output from the image acquired through the scanning electron microscope before performing the preventive maintenance.

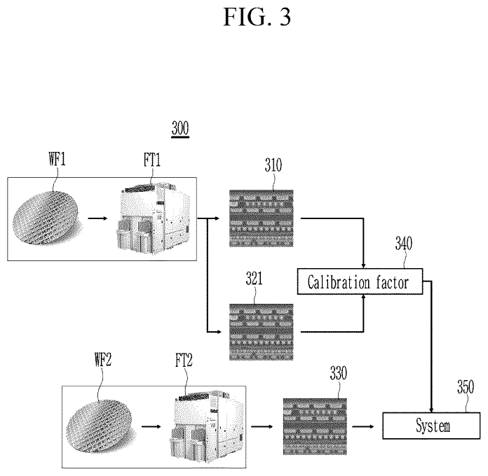

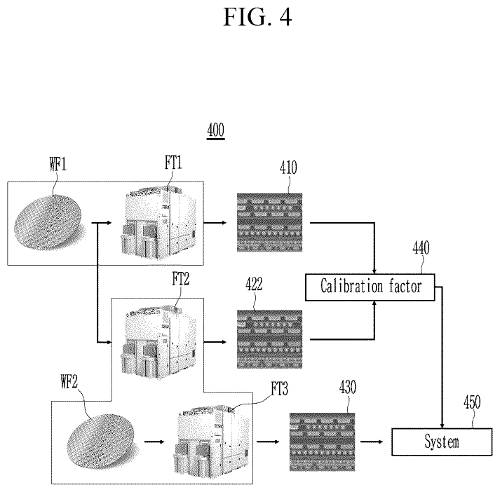

FIG. 3 is an example process of correcting a scanning electron microscope image according to one or more embodiments. FIG. 4 is an example process of correcting a scanning electron microscope image according to one or more embodiments.

Referring to FIG. 3 and FIG. 4, in non-limiting example, processes 300 and 400 illustrate the correction method of the scanning electron microscope image as illustrated in FIG. 2.

In an example, referring to FIG. 3, process 300 may acquire a plurality of scanning electron microscope images for an initial first wafer through the same scanning electron microscope where images of a first wafer WF1 and a second wafer WF2 are acquired through a first scanning electron microscope FT1 and a second scanning electron microscope FT2, respectively.

In an example, the first wafer WF1 and the second wafer WF2 may be different wafers. The first scanning electron microscope FT1 and the second scanning electron microscope FT2 may be different scanning electron microscopes.

The first image 310 and the second image 321 acquired through the first scanning electron microscope FT1 may be different. In other words, the first image 310 and the second image 321 may have different characteristics. Accordingly, the system input result from the first image 310 and the system input result from the second image 321 may be different.

In an example, the first image 310 may be acquired before the preventive maintenance for the first scanning electron microscope FT1, and the second image 321 may be acquired after the preventive maintenance for the first scanning electron microscope FT1.

Therefore, the first image 310 and the second image 321 were acquired through the same first scanning electron microscope FT1 with the same first wafer WF1, but they may have different characteristics due to the different acquisition times.

In an example, in the correction method of the scanning electron microscope image, the calibration factor 340 acquired from the first image 310 and the second image 321 may correct the second image 321 so that the second image 321 outputs a same result value through the system 350 with the same characteristic as the first image 310.

In an example, if the second image 321 and the calibration factor 340 are input together into the system 350, the result for the second image 321 may be the same as the result for the same system (i.e., system 350) of the first image 310 by the calibration factor 340.

The third image 330 acquired through the second scanning electron microscope FT2 may be acquired for the second wafer WF2. The third image 330 acquired for the second wafer WF2 may be input to the system 450 along with the calibration factor.

The third image 330 may be input to the system 350 along with a pre-estimated calibration factor, so that the result value of the system may achieve a state of homeostasis with previous images regardless of the preventive maintenance for the second scanning electron microscope FT2.

Referring to FIG. 4, process 400 may perform a correction of the scanning electron microscope including acquiring a plurality of scanning electron microscope images for the initial first wafer through the plurality of different scanning electron microscopes. The descriptions overlapping with FIG. 3 are omitted.

The first image 410 for the first wafer WF1 may be acquired through the first scanning electron microscope FT1, and the second image 422 may be acquired through the second scanning electron microscope FT2. In other words, the first image 410 and the second image 422 may be obtained at different time points, and thus, the first wafer WF1 may be acquired through a scanning electron microscope that is different from a scanning electron microscope used to acquire other images (i.e., second image 422 through second scanning electron microscope FT2).

The third image 430 for the second wafer WF2 may be acquired through the third scanning electron microscope FT3. The third scanning electron microscope FT3 may be the same as or different from the first scanning electron microscope FT1 and the second scanning electron microscope FT2.

Although the first image 410 and the second image 422 were acquired through the different scanning electron microscopes, they may still be acquired at the different time points for the same first wafer WF1.

Therefore, in an example, the calibration factor 440 may be estimated with the first image 410 and the second image 422 through the correction method of the scanning electron microscope image.

The application of the calibration factor 440 may result in correcting the system input result such that the second image 422 is the same as the system input result for the first image 410. In other words, the calibration factor 440 may maintain the homeostasis for the system input results of the first image 410 and the second image 422 for the same first wafer WF1, regardless of the type of the used scanning electron microscope.

In an example, through the correction method of the scanning electron microscope image according to an embodiment, the second image 422 may be input to the system 450 along with the calibration factor 440, and through the correction, the system input result value may be output to be the same as the result value for the first image 410.

In an example, the calibration factor 440 produced through the correction method of the scanning electron microscope image may also maintain the homeostasis of the system result for the second wafer WF2, which is different from the first wafer WF1.

In other words, the third image 430 acquired for the second wafer WF2 may have different system result values depending on the time points of the acquisition. Therefore, the third image 430 may be corrected by being input to the system 450 along with the calibration factor 440.

In an example, for the second wafer WF2, the system results for the image acquired before the preventive maintenance of the third scanning electron microscope FT3 and the third image 430 acquired after the preventive maintenance may be output differently if they were not input together with the calibration factor 440.

However, if the third image 430 is input to the system 450 along with the calibration factor 440, the result value therefor may be output the same for the second wafer WF2 regardless of the preventive maintenance of the third scanning electron microscope FT3.

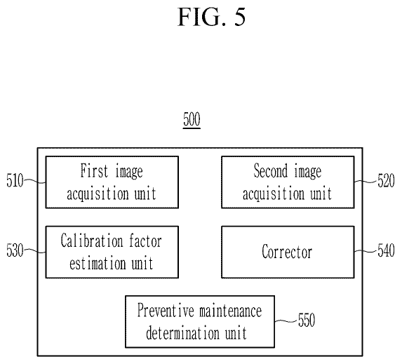

FIG. 5 is an example electronic apparatus with scanning electron microscope image correction according to one or more embodiments.

Referring to FIG. 5, in a non-limiting example, an electronic apparatus 500 (i.e., a scanning electron microscope image correction apparatus) may include a first image acquisition unit 510, a second image acquisition unit 520, a calibration factor estimation unit 530, a corrector 540, and a preventive maintenance determination unit 550.

In an example first image acquisition unit 510 may acquire a first image of a scanning electron microscope from a first wafer at a first time point.

The first image acquisition unit 510 may acquire the first image using a first scanning electron microscope.

The first image acquisition unit 510 may specify the first time point as a time point before performing the preventive maintenance of the scanning electron microscope.

In an example second image acquisition unit 520 may acquire a second image of the scanning electron microscope from the first wafer at a second time point after a predetermined amount of time from the first time point.

The second image acquisition unit 520 may acquire the second image by using a second scanning electron microscope. The second scanning electron microscope may be a scanning electron microscope that is the same as or different from the first scanning electron microscope.

The second image acquisition unit 520 may determine the second time point as a time point when a predetermined period of time has passed after the first time point. In other words, the second image acquisition unit 520 may periodically acquire the scanning electron microscope image of the first wafer. The second image acquisition unit 520 may use the scanning electron microscope image acquired from some or all of the periods of time occurring during the corresponding period of time, and/or during specific time intervals during the corresponding period of time.

The second image acquisition unit 520 may determine the second time point as a specific time point that requires the correction of the first image after the first time point.

The second image acquisition unit 520 may compare the first result obtained by inputting the estimated first image into a training model and the second result obtained by inputting the second image into the training model, and determine a time point when the difference extracted through the comparison satisfies a predetermined condition as the specific time point when the correction is needed.

The second image acquisition unit 520 may specify the second time point as a time point after performing the preventive maintenance.

In an example, the calibration factor estimation unit 530 may estimate the calibration factor by using the first image and the second image.

The calibration factor estimation unit 530 may adjust a candidate calibration factor until the first result obtained by inputting the first image into a training model and the second result obtained by inputting the second image together with the candidate calibration factor into the training model are the same.

The calibration factor estimation unit 530 may finally estimate the candidate calibration factor input along with the second image when the first result and the second result are the same as a calibration factor.

The calibration factor estimation unit 530 may obtain a specific calibration factor that matches the result of the system for the first image and the result of the system for the second image through a trained artificial intelligence (AI) model.

In an example, the corrector 540 may correct the third image of the scanning electron microscope acquired from the second wafer by using the calibration factor.

The corrector 540 may input the third image along with the calibration factor to the training model, including an artificial intelligence system.

The corrector 540 may correct the third image acquired from the second wafer by using the scanning electron microscope after performing the preventive maintenance through the calibration factor.

In an example, the preventive maintenance determination unit 550 may determine that the preventive maintenance of the scanning electron microscope is necessary if the value of the estimated calibration factor is outside a management value range.

FIG. 6 is an example method of determining a preventive maintenance through a correction method of a scanning electron microscope image according to one or more embodiments.

The process of determining the preventive maintenance may be performed through an electronic apparatus (e.g., a scanning electron microscope image correction apparatus). For example, the process of determining the preventive maintenance may be performed through a preventive maintenance determination unit (e.g., preventive maintenance determination unit 550).

Referring to FIG. 6, in a non-limiting example, the scanning electron microscope image correction apparatus (i.e., electronic apparatus 500) may acquire the scanning electron microscope (SEM) image B of the wafer A at the first time point (S610).

In an example, the scanning electron microscope image correction apparatus 100 may acquire a scanning electron microscope image C of the same wafer A at a second time point after the first time point (S620).

In an example, the scanning electron microscope image correction apparatus 100 may produce the calibration factor with the different images B and image C for the same wafer A at the different time points (S630).

In an example, the scanning electron microscope image correction apparatus 100 may determine whether the produced calibration factor satisfies a predetermined specific condition (S640). In an example,, the scanning electron microscope image correction apparatus (i.e., electronic apparatus 500) may determine that the specific condition has been satisfied if the calibration factor is outside a designated management range and determine that a preventive maintenance of the scanning electron microscope equipment is necessary.

In an example, an scanning electron microscope image correction apparatus (i.e., electronic apparatus 500) may perform the preventive maintenance as soon as it is determined that the preventive maintenance is necessary (S650).

If it is not determined that the preventive maintenance is necessary, the scanning electron microscope image correction apparatus 100 may acquire a scanning electron microscope image D for the wafer A with the same scanning electron microscope equipment after a predetermined time point.

FIG. 7 is a graph illustrating an example preventive maintenance determining reference according to one or more embodiments. The scanning electron microscope image correction apparatus (i.e., electronic apparatus 500) may pre-determine a management range of the calibration factor between 0.6 to 0.8.

Referring to FIG. 7, in a non-limiting example, a y-axis may be a calibration factor, and an x-axis may be a passage of a time or a number of measurements.

In an example, a scanning electron microscope image correction apparatus (i.e., electronic apparatus 500) may measure the calibration factor at a regular period. If the calibration factor is measured and found to be within the management range every time the calibration factor is measured, it is determined that the preventive maintenance is not necessary.

In an example, however, a scanning electron microscope image correction apparatus (i.e., electronic apparatus 500) may determine that the preventive maintenance is necessary at the corresponding time point and perform the preventive maintenance when the calibration factor exceeds the management range.

In addition, a scanning electron microscope image correction apparatus (i.e., electronic apparatus 500) may determine that the preventive maintenance is necessary even when a large change suddenly occurs in the estimate value of the calibration factor at a specific measurement time point.

In an example, from the 31st (or 32nd) measured calibration factor in a graph, the value exceeds the management range of 0.8. Therefore, the scanning electron microscope image correction apparatus 100 may determine the need for the preventive maintenance of the scanning electron microscope through a preventive maintenance judgment algorithm at the time point that the 31st (or 32nd) calibration factor is estimated and perform the preventive maintenance of the scanning electron microscope.

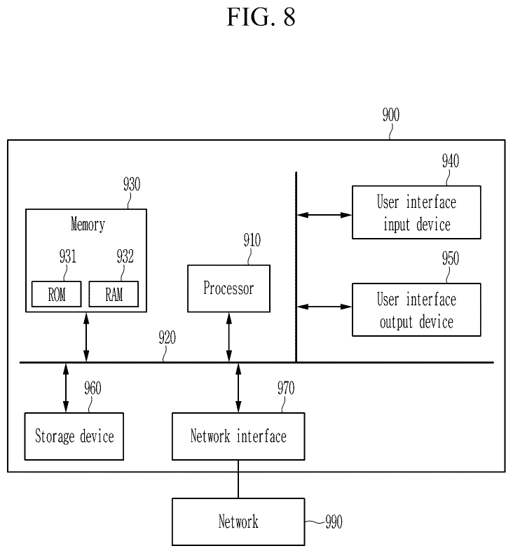

FIG. 8 illustrates an example electronic apparatus according to one or more embodiments.

Referring to FIG. 8, in a non-limiting example, a scanning electron microscope image correction apparatus and a method to correct the scanning electron microscope image may be implemented using electronic apparatus 900.

In an example, the electronic apparatus 900 may include one or more of a processor 910, a memory 930, a user interface input device 940, a user interface output device 950, and a storage device 560 communicating through a bus 920. The electronic apparatus 900 may also include a network interface 970 electrically connected to the network 990. The network interface 970 may transmit or receive signals with other entities through the network 990.

The processor 910 may be configured to execute programs or applications to configure the processor 910 to control the electronic apparatus 900 to perform one or more or all operations and/or methods involving the correction of images from scanning electron microscopes, and may include any one or a combination of two or more of, for example, a central processing unit (CPU), a graphic processing unit (GPU), a neural processing unit (NPU) and tensor processing units (TPUs), but is not limited to the above-described examples. The processor 910 may be configured to implement the functions and methods described above in relation to FIG. 1 to FIG. 7.

The memory 930 may include computer-readable instructions. The processor 910 may be configured to execute computer-readable instructions, such as those stored in the memory 930, and through execution of the computer-readable instructions, the processor 910 is configured to perform one or more, or any combination, of the operations and/or methods described herein. The memory 930 may be a volatile or nonvolatile memory. In an example, the memory 930 may include a read-only memory (ROM) 931 and a random access memory (RAM) 932. In an example, the memory 930 may be positioned inside or outside the processor 910, and the memory 930 may be connected to the processor 910 through various known means.

In an example, at least some of the components or functions of the scanning electron microscope image correction apparatus and the method thereof according to the embodiments may be implemented as a program or a software running on the electronic apparatus 900, and the program or software may be stored in a computer-readable medium.

In some examples, at least some of the components or functions of the scanning electron microscope image correction apparatus and the method thereof according to embodiments may be implemented using hardware or circuits of the electronic apparatus 900, or separate hardware or circuits that may be electrically connected to the electronic apparatus 900.

The electronic apparatuses, processors, memories, neural networks, systems, scanning electron microscopes, first image acquisition unit 510, second image acquisition unit 520, calibration factor estimation unit 530, corrector 540, and preventive maintenance determination unit 550, described herein and disclosed herein described with respect to FIGS. 1-8 are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-8 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method, the method comprising:
acquiring a first image of a first wafer at a first time point;
acquiring a second image of the first wafer at a second time point after a predetermined amount of time from the first time point;
estimating a calibration factor by using the first image and the second image; and
correcting a third image of a second wafer by using the calibration factor.

2. The method of claim 1, further comprising:
acquiring the first image comprises acquiring the first image by using a first scanning electron microscope, and
acquiring the second image comprises acquiring the second image by using a second scanning electron microscope.

3. The method of claim 1, wherein the acquiring of the second image comprises:
determining the second time point as a specific time point that requires the correction of the first image after the first time point.

4. The method of claim 3, wherein the determining of the specific time point comprises:
determining a time point at which a difference extracted by comparing a first result obtained by inputting the first image into a training model and a second result obtained by inputting the second image into the training model satisfies a predetermined condition as a specific point when the correction is required.

5. The method of claim 1, wherein the acquiring of the first image comprises:
specifying the first time point as a time point before performing a preventive maintenance of a scanning electron microscope that acquires one or more of the first image, the second image, and the third image, and
wherein the acquiring of the second image comprises:
specifying the second time point as a time point after performing the preventive maintenance.

6. The method of claim 5, wherein the correcting of the third image comprises:
correcting the third image acquired from the second wafer through the calibration factor by using a scanning electron microscope after performing the preventive maintenance.

7. The method of claim 5, further comprising:
determining that the preventive maintenance of the scanning electron microscope is necessary if an estimated value of the calibration factor is outside a management value range.

8. The method of claim 1, wherein the estimating of the calibration factor comprises:
adjusting a candidate calibration factor until a first result obtained by inputting the first image into a training model and a second result obtained by inputting the second image together with the candidate calibration factor into the training model are the same; and
estimating the candidate calibration factor input along with the second image as a calibration factor when the first result and the second result are the same.

9. The method of claim 1, wherein the estimating of the calibration factor comprises:
obtaining a specific calibration factor that matches a first result of a first system for the first image and a second result of a second system for the second image through neural network.

10. The method of claim 1, wherein the correcting of the third image comprises:
inputting the third image along with the calibration factor to a training model of a neural network.

11. An electronic apparatus, comprising:
processors configured to execute instructions; and
a memory storing the instructions, wherein execution of the instructions configures the processors to:
acquire a first image of a scanning electron microscope from a first wafer at a first time point;
acquire a second image of the scanning electron microscope from the first wafer at a second time point a predetermined period of time after the first time point;
estimate a calibration factor by using the first image and the second image; and
correct a third image of another scanning electron microscope acquired from a second wafer by using the calibration factor.

12. The electronic apparatus of claim 11, wherein the acquiring of the first image is performed using a first scanning electron microscope, and
wherein the acquiring of the second image is performed by using a second scanning electron microscope.

13. The electronic apparatus of claim 11, wherein the acquiring of the second image comprises determining the second time point as a specific time point that the correction of the first image is necessary after the first time point.

14. The electronic apparatus of claim 13, wherein the acquiring of the second image comprises determining a time point when a difference extracted by comparing a first result obtained by inputting the first image into a training model and a second result obtained by inputting the second image into the training model satisfies a predetermined condition as a specific time point that the correction is necessary.

15. The electronic apparatus of claim 11, wherein the acquiring of the first image comprises specifying the first time point as a prior-time point before performing preventive maintenance of the scanning electron microscope, and
wherein the acquiring of the second image comprises specifying the second time point as a post-time point after performing the preventive maintenance.

16. The electronic apparatus of claim 15, wherein the correcting comprises correcting the third image acquired from the second wafer by using the other scanning electron microscope after performing the preventive maintenance through the calibration factor.

17. The electronic apparatus of claim 11, wherein the estimating of the calibration factor comprises adjusting a candidate calibration factor until a first result obtained by inputting the first image into a training model and a second result obtained by inputting the second image together with the candidate calibration factor into the training model are the same, and
wherein, when the first result and the second result are the same, the candidate calibration factor input along with in the second image is estimated as the calibration factor.

18. The electronic apparatus of claim 11, wherein the estimating of the calibration factor comprises obtaining a specific calibration factor that matches a first result of a first system for the first image and a second result of a second system for the second image through trained neural network model.

19. The electronic apparatus of claim 11, wherein the processor is further configured to:
determine that a preventive maintenance of the scanning electron microscope is necessary if an estimated value of the calibration factor is outside a management value range.

20. The electronic apparatus of claim 11, wherein the correction of the third image comprises inputting the third image along with the calibration factor into a training model of a neural network.
